(19) United States
(12) Patent Application Publication
(10) Pub. No.: US 2016/0365873 A1
(43) Pub. Date: Dec. 15, 2016

(54) Non-Binary LDPC Codes Over Non-Associative Finite Division Near Rings

(71) Applicant: Broadcom Corporation, Irvine, CA (US)

(72) Inventors: Matthias KORB, Irvine, CA (US); Andrew Blanksby, Lake Oswego, OR (US)

(73) Assignee: Broadcom Corporation, Irvine, CA (US)

(21) Appl. No.: 14/734,749

(22) Filed: Jun. 9, 2015

(51) Int. Cl. H03M 13/11

(52) U.S. Cl. CPC H03M 13/1114; H03M 13/1171

(57) ABSTRACT

The present disclosure is directed to an apparatus and method for decoding non-binary LDPC codes over non-associative finite division near rings. A non-associative finite division near ring is a type of algebraic structure that includes a finite set of elements on which the operations of addition and multiplication are defined. The operation of addition is commutative, associative, and closed, and may have an additive identity for all elements in the finite set. The operation of multiplication is closed but not commutative or associative, and has a multiplicative inverse but not a multiplicative identity for all elements in the finite set. The two operations of addition and multiplication may be related by the distributive property.

### TECHNICAL FIELD

This application relates generally to message passing (MP) decoders for low-density parity-cheek (LDPC) codes, including MP decoders for non-binary LDPC codes.

### BACKGROUND

Message-passing (MP) algorithms are a class of decoding algorithms that can be used to decode binary parity-check codes. They can perform very close to maximum likelihood (ML) decoding but with much less complexity, allowing for longer codes to be used with better error rates.

At a high-level, MP algorithms involve an iterative exchange of messages between two types of nodes: variable-nodes that each correspond to a respective coded bit, and check-nodes that each correspond to a respective parity-check of the binary parity-check code. Each variable-node exchanges messages with the check-nodes that correspond to the parity-checks that the variable-node's respective coded bit is constrained by. The messages provide an estimation of the variable-node's respective coded bit.

During each iteration, a new message to be transmitted from a variable-node to a check-node or vice-versa is computed in an extrinsic manner such that the message does not depend on the last message received in the opposite direction. For example, a new message transmitted from a check-node to a variable-node is computed by the check-node such that the message does not depend on the last message received in the opposite direction from the variable-node. This constraint on the computation of new messages helps variable-nodes obtain new information about their respective coded bits with each additional iteration, resulting in a steady improvement, rather than self-confirmation, of the variable-node's estimation of its respective coded bit.

In general, a message received by either a variable-node or check-node will undesirably begin to depend on one or more of the messages previously sent by that node after enough iterations, resulting in self-confirmations. To prevent self-confirmations from impacting decoding performance to a significant degree, self-confirmations should occur only after a sufficiently number of iterations have been performed such that the estimations of the coded bits have been sufficiently improved. This requires the number of messages sent and received by the variable-nodes and check-nodes during each iteration to be small or, equivalently, the binary parity-check matrix of the binary parity-check code to be sparse.

Low-density parity-check (LDPC) codes are a type of parity-check code defined by a sparse parity-check matrix, making them ideal for effective decoding by a MP decoder. In fact, LDPC codes were introduced for the purpose of being decoded by MP decoders.

Although described above as being used to decode binary parity-check codes, MP decoders can also be used to decode non-binary parity-check codes. Conventional non-binary MP decoders decode non-binary LDPC codes over finite Galois fields or, more generally, over general linear groups. However, these two algebraic structures do not encompass all possible algebraic structures for non-binary LDPC codes that can be decoded using a MP decoder, leaving out other algebraic structures that can potentially lead to improved decoding performance.

### BRIEF DESCRIPTION OF THE DRAWINGS/FIGURES

The accompanying drawings, which are incorporated herein and form a part of the specification, illustrate the present disclosure and, together with the description, further serve to explain the principles of the disclosure and to enable a person skilled in the pertinent art to make and use the disclosure.

FIG. 1 illustrates an exemplary communication system in which embodiments of the present disclosure can be implemented.

FIG. 2 illustrates an example parity-check matrix and corresponding MP decoder in accordance with embodiments of the present disclosure.

FIG. 3 illustrates the computation of messages sent from variable-nodes to check-nodes and vice-versa in accordance with embodiments of the present disclosure.

FIG. 4 provides an example Cayley table for a finite Galois field with 4 elements.

FIG. 5 provides three example Cayley tables for a non-associative finite division near ring with 4 elements in accordance with embodiments of the present disclosure.

FIG. 6 provides three example Cayley tables for an extended non-associative finite division near ring with 4 elements in accordance with embodiments of the present disclosure.

FIG. 7 illustrates an exemplary flowchart of a method for exchanging messages between variable-nodes and check-nodes in a MP decoder for decoding non-binary LDPC codes over non-associative finite division near rings in accordance with embodiments of the present disclosure.

FIG. 8 illustrates a block diagram of an example computer system that can be used to implement aspects of the present disclosure.

The present disclosure will be described with reference to the accompanying drawings. The drawing in which an element first appears is typically indicated by the leftmost digit(s) in the corresponding reference number.

### DETAILED DESCRIPTION

In the following description, numerous specific details are set forth in order to provide a thorough understanding of the disclosure. However, it will be apparent to those skilled in the art that the disclosure, including, structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring aspects of the disclosure.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of this discussion, the term “module” or “node” (e.g., check-node or variable-node) shall be understood to include software, firmware, or hardware (such as one or more circuits, microchips, processors, and/or devices), or any combination thereof. In addition, it will be understood that each module or node can include one, or more than one, component within an actual device, and each component that forms a part of the described module or node can function either cooperatively or independently of any other component forming a part of the module or node. Conversely, multiple modules or nodes described herein can represent a single component within an actual device. Further, components within a module or node can be in a single device or distributed among multiple devices in a wired or wireless manner.

### 1. Overview

The present disclosure is directed to message passing (MP) decoders for non-binary LDPC codes over non-associative finite division near rings. A non-associative finite division near ring is a type of algebraic structure that includes a finite set of elements on which the operations of addition and multiplication are defined. The operation of addition may be commutative, associative, and closed, and may have an additive identity for all elements in the finite set. The operation of addition further has an additive inverse for all elements in the finite set. The operation of multiplication is closed but not commutative or associative, and has a multiplicative inverse but does not have a multiplicative identity for all elements in the finite set. The two operations of addition and multiplication may be related by the distributive property.

The properties of the multiplication operation in non-associative finite division near rings differ from the properties of the multiplication operation in general linear groups and finite Galois fields. Specifically, unlike non-associative finite division near rings, multiplication is associative in general linear groups and finite Galois fields. Because of this difference, a non-associative finite division near ring can be described by Cayley tables that cannot be used to describe a general linear group or finite Galois fields that includes the same finite set of elements.

A Cayley table describes the multiplication operation of an algebraic structure by arranging one set of possible products for all combinations of two elements in the algebraic structure in a square table similar to a multiplication table. Because any set of products can be used for an algebraic structure so long as the chosen set does not violate one of the algebraic structure's properties (e.g., the associative property of multiplication), an algebraic structure that includes a particular finite set of elements may be described by several different Cayley tables.

The MP decoders of the present disclosure are configured to decode non-binary LDPC codes over non-associative finite division near rings by performing multiplication operations in accordance with Cayley tables that cannot be used by conventional MP decoders for non-binary LDPC codes over finite Galois fields and general linear groups. It can be shown that the MP decoders of the present disclosure can provide better block error performance than the conventional MP decoders. Before further describing these and other features of the present disclosure, an exemplary operating environment in which embodiments of the present disclosure can be implemented is provided.

2. Exemplary Operating Environment

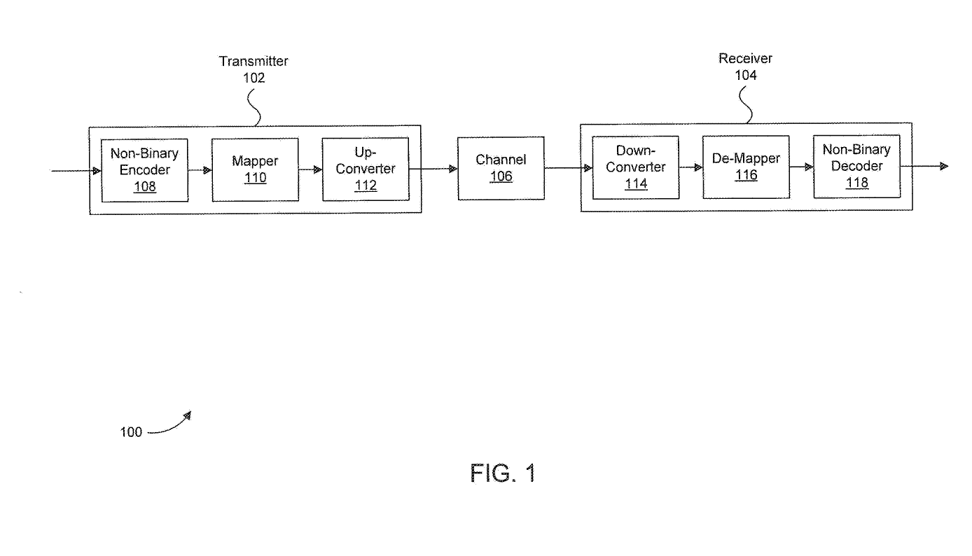

FIG. 1 illustrates an exemplary communication system 100 in which embodiments of the present disclosure can be implemented. Communication system 100 includes a transmitter 102 and a receiver 104. Transmitter 102 transmits messages to receiver 104 over a channel 106 that can be, for example, a wired or wireless medium. Channel 106 can be modeled as a Binary Symmetric channel, an Additive White Gaussian Noise channel, a Fading channel, or an Erasure channel, for example.

In operation, messages of length K to be transmitted are first received by a non-binary encoder 108 of transmitter 102. Non-binary encoder 108 is configured to encode the messages in accordance with a block code by producing a unique code word of length N for each message using algebraic operations over the message, where N>K and the N codeword symbols and K information symbols are chosen from the non-binary alphabet of size q>2. Because N is greater than K, the q^{K} possible message sequences are mapped onto only a fraction of the q^{N} different N-length codewords.

In the embodiment of FIG. 1, non-binary encoder 108 is specifically configured to encode the messages in accordance with a non-binary low-density binary parity-check (LDPC) code. The codewords in such a non-binary parity-check code can be formed, for example, by combining the K message symbols with N-K parity-check symbols. Each parity-check symbol is the sum of a pre-specified set of the K message bits. Other non-systematic non-binary parity-check codes can be used as will be appreciated by one of ordinary skill in the art.

After the messages have been encoded, the resulting N-length codewords are mapped by a mapper 110 onto complex channel symbols and up-converted by an up-converter 112 to one or more carrier frequencies for transmission over channel 106. For the sake of simplicity, it is assumed that each non-binary code symbol is mapped into a different channel symbol by mapper 110. However, embodiments of the present disclosure are not so limited and can be used in communication systems that use different non-binary code symbol to channel symbol mappings as would be appreciated by one of ordinary skill in the art.

On the side of receiver 104 down-converter 114 and de-mapper 116 first down-convert the received carriers to baseband and de-map the channel symbols into soft non-binary code symbol values of the encoded messages. The soft non-binary code symbol values can represent, for example, the likelihood that a received channel symbol (or, more precisely, its corresponding complex sample from the baseband signal) represents a particular non-binary code symbol.

Non-binary decoder 118 is a message passing (MP) decoder configured to perform iterative decoding to determine the transmitted codewords (and thereby the transmitted messages) from the soft symbol values provided by de-mapper 116.

3. General MP Decoder Structure for Non-Binary LDPC Codes

Before describing specific embodiments of the present disclosure, a description of a generalized MP decoder for non-binary LDPC codes is provided. The following notations are used in the description of the generalized MP decoder and are listed here for quick reference:
G_{q}={0, 1, . . . q−1} is the generic algebraic structure with q elements, also referred to as non-binary symbols;
H is the sparse q-ary parity-check matrix with dimension N×M for the non-binary LDPC code;
x=(x₁, . . . , x_{N}) is the q-ary codeword that satisfies Hx^{T}0;
[symbol] is the bipartite graph representing the generalized MP decoder;
[symbol] ={ν₁, . . . , ν_{N}} is the set of variable nodes in [symbol] ;
[symbol] ={c₁, . . . , c_{M}} is a set of check nodes in [symbol] ;
[symbol] (νₙ) is the set of check-nodes connected to the variable-node νₙ, also referred to as the neighbor check-nodes of the variable-node νₙ;
[symbol] (cₘ) is the set of variable-nodes connected to the check-node cₘ, also referred to as the neighbor variable-nodes of the check-node cₘ;
α_{m,n}=(α_{m,n}(α))_{α∈G}_{_{q}} is the q-tuple message sent from the variable-node νₙ to check-node cₘ;
β_{m,n}=(β_{m,n}(α))_{α∈G}_{_{q}} is the q-tuple message sent from the check-node cₘ to the variable-node νₙ; and
γₙ=(γₙ(α))_{α∈G}_{_{q}} is the a priori information supplied to MP decoder, providing the likelihood of the n-th transmitted symbol being equal to α for all α∈G_{q}.

In general, a non-binary LDPC code over a generic algebraic structure G_{q} with q elements (or non-binary symbols) is defined by a sparse q-ary parity-check matrix H with dimension N×M. A codeword is a vector x=(x₁, . . . , x_{N})∈G_{q}^{N} that satisfies Hx^{T}=0.

The generalized MP decoder can be represented by a bipartite graph [symbol] , meaning that the graph is separated into two distinct sets of nodes and edges of the graph only connect nodes of different types. The two sets of nodes are variable-nodes [symbol] ={ν₁, . . . , ν_{N}} and check-nodes [symbol] ={c₁, . . . , c_{M}}. A variable-node νₙ and a check-node cₘ are connected by an edge if and only if the element h_{m,n} in H is non-null, where the edge has a weight equal to h_{m,n}. Put differently, each variable-node νₙ corresponds to a coded bit and each check-node cₘ corresponds to a parity-check equation of the non-binary LDPC code. A variable-node νₙ and a check-node cₘ are connected by an edge if and only if the corresponding parity-check equation of the check-node cₘ constrains the corresponding coded bit of the variable-node νₙ. The notation [symbol] (νₙ) is used to denote the set of check-nodes connected to the variable-node νₙ, and the notation [symbol] (cₘ) is used to denote the set of variable-nodes connected to the check-node cₘ.

MP decoders are iterative decoders that pass messages in both directions of the edges. During each iteration, a new message to be transmitted over an edge from a variable-node νₙ to a check-node cₘ or vice-versa is computed in an extrinsic manner such that the message is a function of all the messages received by the sender node from its neighbor nodes except the message received over the same edge that the new message is sent. For example, a new message to be transmitted over an edge from a check-node cₘ to a variable-node νₙ is computed by the check-node cₘ such that the message is a function of all messages received from its neighbor variable-nodes [symbol] (cₘ) except the message received from the variable-node νₙ.

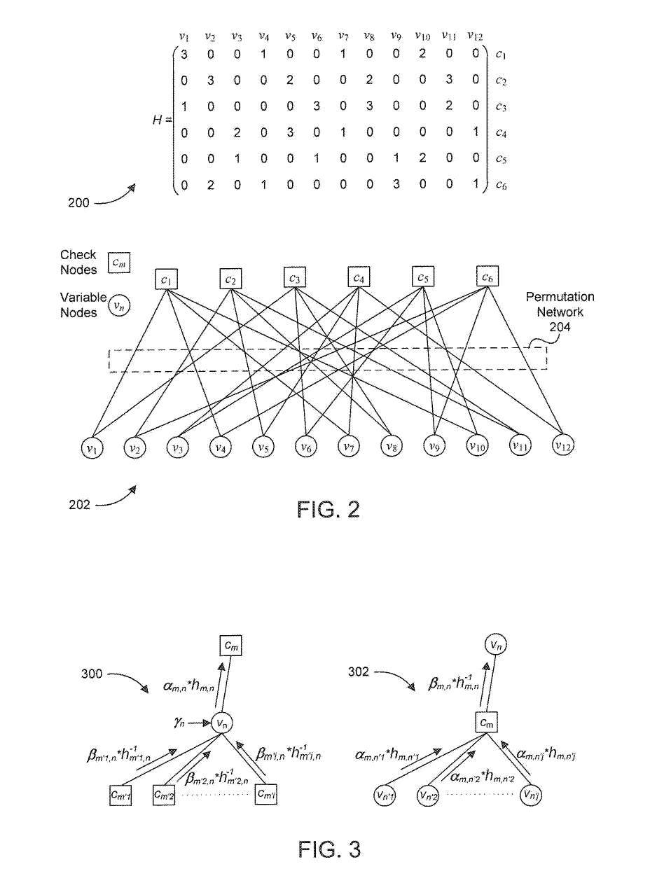

FIG. 2 illustrates an example parity-check matrix 200 and corresponding MP decoder 202 having variable nodes ν₁-ν₁₂ and check nodes c₁-c₆. Parity-check matrix 200 defines a non-binary LDPC code over the generic algebraic structure G_{q}. Although it can be seen from parity-check matrix 200 in FIG. 2 that q is specifically equal to 4, the variable q is used here for generalization purposes. The variable nodes ν₁-ν₁₂ and check nodes c₁-c₆ can be one or more processors or logic circuits.

It can be verified that a variable-node νₙ and a check-node cₘ in MP decoder 202 are connected by an edge if and only if the element h_{m,n} in parity-check matrix 200 is non-null, where the edge has a weight equal to h_{m,n} that is applied by a permutation network 204 in a manner explained later in the discussion below. Put differently, as provided above, each variable-node νₙ corresponds to a coded bit and each check-node cₘ corresponds to a parity-check equation of the non-binary LDPC code. A variable-node νₙ and a check-node cₘ are connected by an edge if and only if the corresponding parity-check equation of the check-node cₘ constrains the corresponding coded bit of the variable-node νₙ. For example, in FIG. 2 check-node c₁ corresponds to the parity-check equation 0=3ν₁⊕ν₄⊕ν₇⊕2ν₁₀ as defined by the first row in parity-check matrix 200. Thus, because variable-nodes ν₁, ν₄, ν₇, and ν₁₀ are all constrained by the parity-check equation of check-node c₁, they are each connected by an edge to check-node c₁.

During each iteration of the MP algorithm performed by MP decoder 202, a new message to be transmitted over an edge from a variable-node νₙ to a check-node cₘ or vice-versa is computed in an extrinsic manner as described above. Because MP decoder 202 is configured to decode a non-binary LDPC code over the generic algebraic structure G_{q}, the exchanged messages are q-tuples, with each element of the q-tuple corresponding to a different one of the q symbols in G_{q}. The exchange and computation of such messages between a variable-node νₙ and check-node cₘ is illustrated in FIG. 3.

Specifically, diagram 300 in FIG. 3 illustrates the computation of the message α_{m,n}=(α_{m,n}(α))_{α∈G}_{_{q}}, which is sent from variable-node νₙ to check-node cₘ. The message α_{m,n} is computed by variable-node νₙ as a function of the last messages β_{m′,n}=(β_{m′,n}(α))_{α∈G}_{_{q}}, received by variable-node νₙ from its neighbor check-nodes c_{m′}∈ [symbol] (νₙ)\{cₘ}, and γₙ=(γₙ(α))_{α∈G}_{_{q}}. The q-tuple γₙ is the a priori information supplied to MP decoder 202 that provides the likelihood of the n-th transmitted symbol being equal to α for all α∈G_{q}. The a priori information can be supplied to MP decoder 202 from a de-mapper, such as de-mapper 116 in FIG. 1.

Diagram 302 in FIG. 3 illustrates the computation of the message β_{m,n}=(β_{m,n}(α))_{α∈G}_{_{q}}, which is sent from check-node cₘ to variable-node νₙ. The message β_{m,n} is computed by check-node cₘ as a function of the last messages α_{m,n′}=(α_{m,n′}(α))_{α∈G}_{_{q}}, received by check-node cₘ from its neighbor variable-nodes ν_{n′}∈ [symbol] (cₘ)\{νₙ}.

As further shown in FIG. 3, the messages transmitted along the edges are multiplied by either the weight of the edge or its inverse. More specifically, the edge coupling variable-node νₙ to check-node cₘ in diagrams 300 and 302 multiplies the message α_{m,n}=(α_{m,n}(α))_{α∈G}_{_{q}} by the weight of the edge h_{m,n} given by parity-check matrix 200, and the message β_{m,n}=(β_{m′,n}(α))_{α∈G}_{_{q}} by the inverse weight of the edge h_{m,n}⁻¹.

It should be noted that, during each iteration, the variable-node νₙ typically computes a new a posteriori value for the n-th transmitted symbol as a function of the a priori information γₙ and the last messages β_{m,n} received from the variable-node νₙ from all its neighbor check-nodes cₘ∈ [symbol] (νₙ). MP decoder 202 can stop performing iterations when an estimate of the transmitted codeword, estimated using the a posteriori information from all variable-nodes νₙ in MP decoder 202, is a valid codeword x or after a maximum number of iterations have been performed.

The different MP decoding algorithms, such as the sum-product, min-sum, min-max, Fourier transform decoding algorithms, and various layered decoding algorithms, to name a few, are all consistent with the functionality described above for the generalized MP decoder 202 and, therefore, can be performed by the generalized MP decoder 202. These different MP decoding algorithms generally differ only in the content of the messages exchanged between variable- and check-nodes and in how the messages are computed.

### 4. MP Decoder for Non-Binary LDPC Codes Over Non-Associative Finite Division Near Rings

Conventional non-binary MP decoders decode non-binary LDPC codes over finite Galois fields or, more generally, General Linear Groups. As a result, the multiplication of messages by the weight (or inverse weight) of the edge they are transmitted over would be performed in accordance with a Cayley table that is consistent with all of the properties of finite Galois fields or General Linear Groups, depending on which of the two algebraic structures the non-binary LDPC code is over.

A Cayley table describes the multiplication operation of an algebraic structure by arranging one set of possible products for all combinations of two elements in the algebraic structure in a square table similar to a multiplication table. Because any set of products can be used for an algebraic structure so long as the chosen set does not violate one of the algebraic structure's properties (e.g., the associative property of multiplication), an algebraic structure that includes a particular finite set of elements may be described by several different Cayley tables.

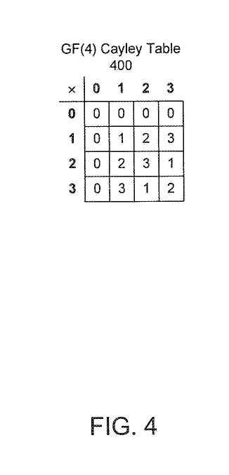

FIG. 4 provides an example Cayley table 400 for the finite Galois field, denoted by GF(q=4), where the value at the intersection of each row and column in Cayley table 400 is the product of the corresponding row and column numbers. As can be seen from FIG. 4, each row in Cayley table 400 except the first row is a permutation of the elements of the field. For any finite Galois field, this will always be the case.

Assuming the generalized MP decoder 200 described above in regard to FIG. 2 decodes non-binary LDPC codes over GF(q=4) with a multiplication operation described by Cayley table 400, the multiplication of the message α_{m,n}=(α_{m,n}(α))_{α∈GF}_{_{q}} transmitted from the variable-node νₙ to the check-node cₘ by the weight of the edge h_{m,n} would result in a permutation of the elements of the message α_{m,n}. For example, assuming h_{m,n}=2 (corresponding to row 2 of Cayley table 400), α_{m,n}(0) permutes to α_{m,n}(0), α_{m,n}(1) permutes to α_{m,n}(2), α_{m,n}(2) permutes to α_{m,n}(3), and α_{m,n}(3) permutes to α_{m,n}(1). Put differently, α_{m,n}*h_{m,n}={α_{m,n}(0), α_{m,n}(3), α_{m,n}(1), α_{m,n}(2)}. The multiplication of the message β_{m,n}=(β_{m′,n}(α))_{α∈G}_{_{q}} by the inverse weight of the edge h_{m,n}⁻¹ would result in the opposite permutation of the elements of the message β_{m,n}.

Permutation network 204 shown in FIG. 2 can perform these permutations for each edge. For example, and in one embodiment, permutation network 204 can include a network of wires or connections that couple the various inputs and outputs of the variable-nodes and check-nodes together in such a way that the messages exchanged between these two types of nodes are permuted in accordance with a given Cayley table and set of edge weights in a parity-check matrix. In another embodiment, permutation network 204 can be implemented in software to perform this functionality.

The present disclosure is directed to MP decoders for decoding non-binary LDPC codes over non-associative finite division near rings. The MP decoders of the present disclosure can be implemented in a communication system, such as communication system 100 in FIG. 1, and in accordance with the generalized MP decoder 202 shown in FIG. 2. The MP decoders of the present disclosure can perform any specific MP algorithm, such as the sum-product, min-sum, min-max, Fourier transform decoding algorithm, layered decoding algorithm, or any other yet to be discovered MP algorithm that is consistent with the functionality described above for the generalized MP decoder 202.

A non-associative finite division near ring is a type of algebraic structure that includes a finite set of elements on which the operations of addition and multiplication are defined. The operation of addition may be commutative (a+b=b+a), associative (a+(b+c)=(a+b)+c), and closed (sum of any two elements in the finite set is also an element of the set), and may have an additive identity (a ‘0’ element such that a+0=a) for all elements in the finite set. The operation of addition further has an additive inverse (for an element ‘a’ there exists an element ‘b’ such that a+b=0) for all elements in the finite set. The operation of multiplication is closed (product of any two elements in the finite set is also an element of the set) but not commutative (ab≠ba) or associative (a(bc)=(ab)c), and has a multiplicative inverse (for an element a there exists an element c such that ac=1) for all elements in the finite set but not a multiplicative identity (a ‘1’ element such that a1=a). The two operations of addition and multiplication may be related by the distributive property (a(b+c)≠ab°ac).

The properties of the multiplication operation in non-associative finite division near rings differ from the properties of the multiplication operation in general linear groups and finite Galois fields. Specifically, unlike non-associative finite division near rings, multiplication is associative in general linear groups and finite Galois fields. Because of this difference, a non-associative finite division near ring can be described by Cayley tables that cannot be used to describe a general linear group or finite Galois fields that includes the same finite set of elements.

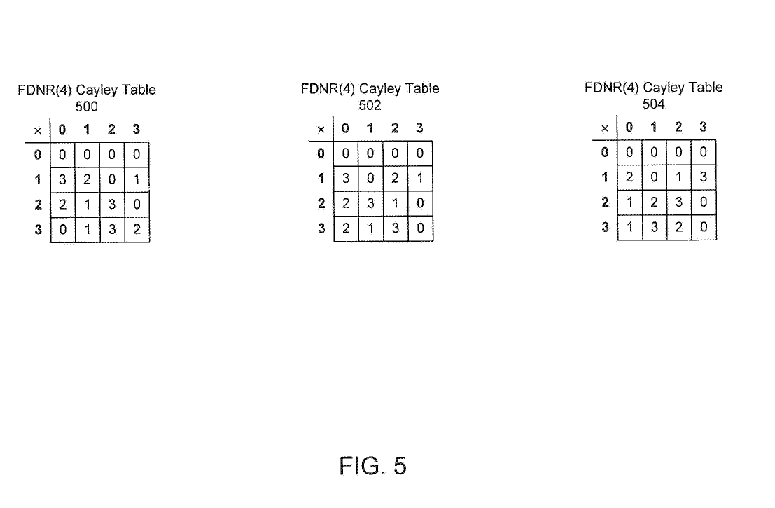

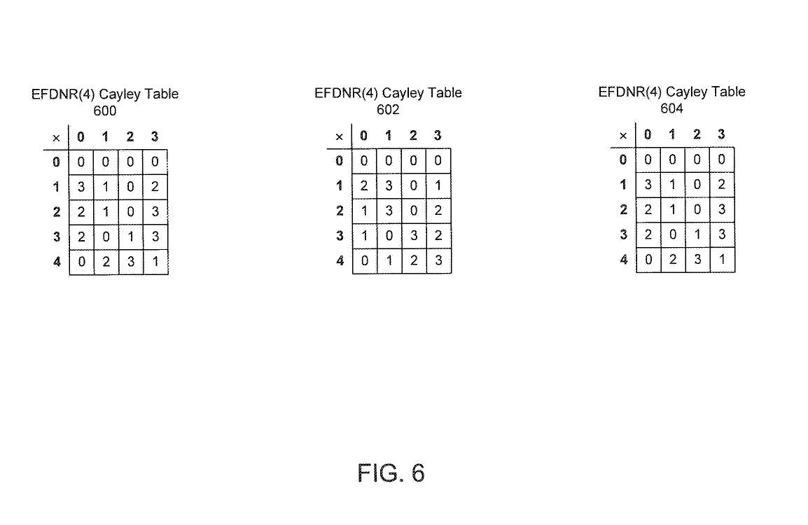

FIG. 5 provides three example Cayley tables 500, 502, and 504 for a non-associative finite division near ring with 4 elements, denoted FDNR(q=4). The value at the intersection of each row and column in Cayley tables 500, 502, and 506 is the product of the corresponding row and column numbers. As can be seen from FIG. 5, each row in Cayley tables 500, 502, and 504 except the first row is a permutation of the elements of the field. The MP decoders of the present disclosure can be implemented to decode non-Binary LDPC codes over a non-associative finite division near ring described by Cayley tables 500, 502, and 504.

For example, assuming the generalized MP decoder 202 described above is used to decode non-binary LDPC codes over FDNR(q=4) with a multiplication operation described by Cayley table 500, the multiplication of the message α_{m,n}=(α_{m,n}(α))_{α∈GF}_{_{q}} transmitted from the variable-node νₙ to the check-node cₘ by the weight of the edge h_{m,n} would result in a permutation of the elements of the message α_{m,n}. For example, assuming h_{m,n}=2 (corresponding to row 2 of Cayley table 500), α_{m,n}(0) permutes to α_{m,n}(2), α_{m,n}(1) permutes α_{m,n}(1), α_{m,n}(2) permutes to α_{m,n}(3), and α_{m,n}(3) permutes to α_{m,n}(0). Put differently, α_{m,n}*h_{m,n}={α_{m,n}(3), α_{m,n}(1), α_{m,n}(2), α_{m,n}(3)}. The multiplication of the message β_{m,n}=(β_{m′,n}(α))_{α∈G}_{_{q}} by the inverse weight of the edge h_{m,n}⁻¹ would result in the opposite permutation of the elements of the message β_{m,n}.

Permutation network 204, shown in FIG. 2 can perform these permutations for each edge. For example, and as described above, permutation network 204 can include a network of wires or connections that couple the various inputs and outputs of the variable-nodes and check-nodes together in such a way that the messages exchanged between these two types of nodes are permuted in accordance with a given Cayley table and set of edge weights provided by a parity-check matrix. In another embodiment, permutation network 204 can be implemented in software (e.g., through instructions that are stored in a memory and executed by a processor) to perform this functionality.

In one embodiment, the network of wires or connections of permutation network 204 are dynamically reconfigurable such that the messages exchanged between the variable-nodes and check-nodes can be permuted in accordance with any one of a plurality of different Cayley tables. For example, MP decoder 202 can include a separate controller to configure permutation network 204 in accordance with a Cayley table for a non-associative finite division near ring when such a non-conventional algebraic structure is supported and used by a transmitter to encode codewords that MP decoder 202 is currently decoding. When such a non-conventional algebraic structure is not supported or used by a transmitter to encode codewords that MP decoder 202 subsequently later decodes, the separate controller can reconfigure permutation network 204 in accordance with a Cayley table for the conventional algebraic structure (e.g., a finite Galois field or general linear group) used by the transmitter to encode the codewords.

Cayley tables 500, 502, and 504 cannot be used by MP decoders for non-binary LDPC codes over finite Galois fields and general linear groups with q=4 because they do not obey at least the associative property of multiplication required by these algebraic structures. It can be shown that the MP decoders of the present disclosure for decoding non-Binary LDPC codes over a non-associative finite division near ring described by Cayley tables 500, 502, and 504 (and others) can provide better block error performance than the conventional MP decoders.

FIG. 6 provides three additional example Cayley tables 600, 602, and 604 for an extended non-associative finite division near ring with 4 elements, denoted FDNR(q=4). The value at the intersection of each row and column in Cayley tables 600, 602, and 604 is the product of the corresponding row and column numbers. As can be seen from FIG. 6, each row in Cayley tables 600, 602, and 604 except the first row is a permutation of the elements of the field. The MP decoders of the present disclosure can be further implemented to decode non-Binary LDPC codes over a non-associative finite division near ring described by Cayley tables 600, 602, and 604. In such a case, the parity-check matrix H can include elements selected from the finite set {0, 1, 2, 3, 4}.

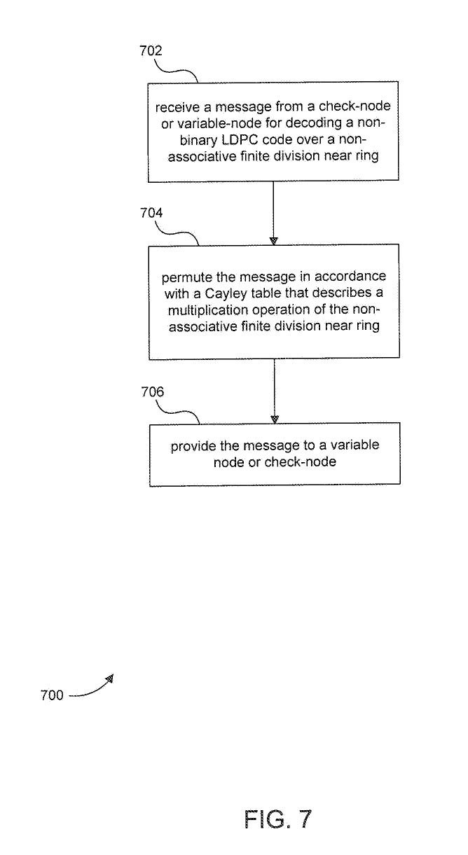

Referring now to FIG. 7, a flowchart 700 of a method for exchanging messages between variable-nodes and check-nodes in a MP decoder for decoding non-binary LDPC codes over non-associative finite division near ring in accordance with embodiments of the present disclosure is illustrated.

The method of flowchart 700 begins at step 702. At step 702, message is received from a check-node or variable-node by a permutation network, such as permutation network 204 in FIG. 3. The message is specifically a message computed by the check-node or variable-node for decoding a non-binary LDPC code over a non-associative finite division near ring.

After step 702, the method of flowchart 700 transitions to step 704. At step 704, the received message is permuted in accordance with a Cayley table that describes a multiplication operation of the non-associative finite division near ring, as well as the weight (or inverse weight) of the edge over which the message is transmitted. Some examples of such tables were given in FIG. 5 and FIG. 6. However, it will be appreciated that other Cayley tables can be used, including those that describe non-associative finite division near rings with additional elements (e.g., 8, 16, or even 32 elements).

After step 704, the method of flowchart 700 transitions to step 706. At step 706, the permuted message is provided to a variable-node (assuming the message was originally received from a check-node) or to a check-node (assuming the message was originally received from a variable-node).

It should be noted that, although the above description has been centered on LDPC decoding, one of ordinary skill in the art will recognize that the non-associative finite division near rings are also applicable to the encoding process. For example, in FIG. 1 a non-binary encoder 108 is shown that, as described above, encodes messages of length K in accordance with a block code to produce codewords of length N, where N>K and the N codeword symbols and K information symbols are chosen from the non-binary alphabet of size q>2. To produce the codewords, non-binary encoder 108 can specifically perform a matrix multiplication Gp=x, where G is a q-ary generator matrix, p is a message to be encoded, and x is a q-ary codeword. The matrix multiplication is performed in accordance with a Cayley table that describes a multiplication operation of the non-associative finite division near ring. For example, the multiplication can be performed in accordance with one of the Cayley tables shown in FIG. 5 or FIG. 6. A matrix multiplier, implemented in either hardware or software, can perform the matrix multiplication Gp. As an alternative to using a generator matrix G. an H-matrix based encoding scheme (e.g. back substitution) can be used to encode a message.

### 5. Example Computer System Environment

It will be apparent to persons skilled in the relevant art(s) that various elements and features of the present disclosure, as described herein, can be implemented in hardware using analog and/or digital circuits, in software, through the execution of instructions by one or more general purpose or special-purpose processors, or as a combination of hardware and software.

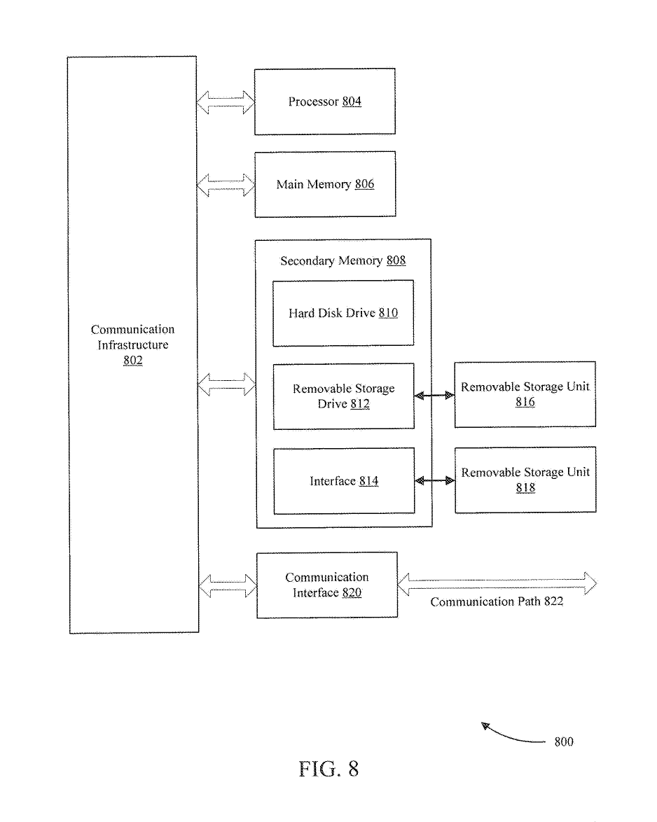

The following description of a general purpose computer system is provided for the sake of completeness. Embodiments of the present disclosure can be implemented in hardware, or as a combination of software and hardware. Consequently, embodiments of the disclosure may be implemented in the environment of a computer system or other processing system. An example of such a computer system 800 is shown in FIG. 8. Modules and nodes depicted in FIGS. 1, 2, and 3 may execute on one or more computer systems 800. Furthermore, each of the steps of the methods depicted in FIG. 7 can be implemented on one or more computer systems 800.

Computer system 800 includes one or more processors, such as processor 804. Processor 804 can be a special purpose or a general purpose digital signal processor. Processor 804 is connected to a communication infrastructure 802 (for example, a bus or network). Various software implementations are described in terms of this exemplary computer system. After reading this description, it will become apparent to a person skilled in the relevant art(s) how to implement the disclosure using other computer systems and/or computer architectures.

Computer system 800 also includes a main memory 806, preferably random access memory (RAM), and may also include a secondary memory 808. Secondary memory 808 may include, for example, a hard disk drive 810 and/or a removable storage drive 812, representing a floppy disk drive, a magnetic tape drive, an optical disk drive, or the like. Removable storage drive 812 reads from and/or writes to a removable storage unit 816 in a well-known manner. Removable storage unit 816 represents a floppy disk, magnetic tape, optical disk, or the like. which is read by and written to by removable storage drive 812. As will be appreciated by persons skilled in the relevant art(s), removable storage unit 816 includes a computer usable storage medium having stored therein computer software and/or data.

In alternative implementations, secondary memory 808 may include other similar means for allowing computer programs or other instructions to be loaded into computer system 800. Such means may include, for example, a removable storage unit 818 and an interface 814. Examples of such means may include a program cartridge and cartridge interface (such as that found in video game devices), a removable memory chip (such as an EPROM, or PROM) and associated socket, a thumb drive and USB port, and other removable storage units 818 and interfaces 814 which allow software and data to be transferred from removable storage unit 818 to computer system 800.

Computer system 800 may also include a communications interface 820. Communications interface 820 allows software and data to be transferred between computer system 800 and external devices. Examples of communications interface 820 may include a modem, a network interface (such as an Ethernet card), a communications port, a PCMCIA slot and card, etc. Software and data transferred via communications interface 820 are in the form of signals which may be electronic, electromagnetic, optical, or other signals capable of being received by communications interface 820. These signals are provided to communications interface 820 via a communications path 822. Communications path 822 carries signals and may be implemented using wire or cable, fiber optics, a phone line, a cellular phone link, an RF link and other communications channels.

As used herein, the terms “computer program medium” and “computer readable medium” are used to generally refer to tangible storage media such as removable storage units 816 and 818 or a hard disk installed in hard disk drive 810. These computer program products are means for providing software to computer system 800.

Computer programs (also called computer control logic) are stored in main memory 806 and/or secondary memory 808. Computer programs may also be received via communications interface 820. Such computer programs, when executed, enable the computer system 800 to implement the present disclosure as discussed herein. In particular, the computer programs, when executed, enable processor 804 to implement the processes of the present disclosure, such as any of the methods described herein. Accordingly, such computer programs represent controllers of the computer system 800. Where the disclosure is implemented using software, the software may be stored in a computer program product and loaded into computer system 800 using removable storage drive 812, interface 814, or communications interface 820.

In another embodiment, features of the disclosure are implemented primarily in hardware using, for example, hardware components such as application-specific integrated circuits (ASICs) and gate arrays. Implementation of a hardware state machine so as to perform the functions described herein will also be apparent to persons skilled in the relevant art(s).

### 6. CONCLUSION

Embodiments have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

What is claimed is:

1. A message passing (MP) decoder, comprising:
a plurality of variable-nodes;
a plurality of check-nodes; and
a permutation network configured to receive messages from the plurality of check-nodes for decoding a non-binary low-density parity-check (LDPC) code over a non-associative finite division near ring, permute the messages in accordance with a Cayley table that describes a multiplication operation of the non-associative finite division near ring, and provide the permuted messages to the plurality of variable-nodes.

2. The MP decoder of claim 1, wherein the plurality of check-nodes are configured to compute the messages in accordance with a sum-product MP decoding algorithm, a min-sum MP decoding algorithm, a min-max MP decoding algorithm, a Fourier transform MP decoding algorithm, or a layered decoding algorithm.

3. The MP decoder of claim 1, wherein the plurality of check-nodes are configured to compute each of the messages in an extrinsic manner.

4. The MP decoder of claim 1, wherein the MP decoder is implemented for a Binary Symmetric channel, an Additive White Gaussian Noise channel, a Fading channel, or an Erasure channel.

5. The MP decoder of claim 1, wherein the Cayley table is given by:

| x | 0 | 1 | 2 | 3 |
|---|---|---|---|---|
| 0 | 0 | 0 | 0 | 0 |
| 1 | 3 | 2 | 0 | 1 |
| 2 | 2 | 1 | 3 | 0 |
| 3 | 0 | 1 | 3 | 2, |
| x | 0 | 1 | 2 | 3 |
|---|---|---|---|---|
| 0 | 0 | 0 | 0 | 0 |
| 1 | 3 | 0 | 2 | 1 |
| 2 | 2 | 3 | 1 | 0 |
| 3 | 2 | 1 | 3 | 0, |

or

| x | 0 | 1 | 2 | 3 |
|---|---|---|---|---|
| 0 | 0 | 0 | 0 | 0 |
| 1 | 2 | 0 | 1 | 3 |
| 2 | 1 | 2 | 3 | 0 |
| 3 | 1 | 3 | 2 | 0 |

where the value at the intersection of each row and column in the Cayley table is the product of the corresponding row and column numbers.

6. The MP decoder of claim 1, wherein the Cayley table is given by:

| x | 0 | 1 | 2 | 3 |
|---|---|---|---|---|
| 0 | 0 | 0 | 0 | 0 |
| 1 | 3 | 1 | 0 | 2 |
| 2 | 2 | 1 | 0 | 3 |
| 3 | 2 | 0 | 1 | 3 |
| 3 | 0 | 2 | 3 | 1, |
| x | 0 | 1 | 2 | 3 |
|---|---|---|---|---|
| 0 | 0 | 0 | 0 | 0 |
| 1 | 2 | 3 | 0 | 1 |
| 2 | 1 | 3 | 0 | 2 |
| 3 | 1 | 0 | 3 | 2 |
| 3 | 0 | 1 | 2 | 3, |

or

| x | 0 | 1 | 2 | 3 |
|---|---|---|---|---|
| 0 | 0 | 0 | 0 | 0 |
| 1 | 3 | 1 | 0 | 2 |
| 2 | 2 | 1 | 0 | 3 |
| 3 | 2 | 0 | 1 | 3 |
| 3 | 0 | 2 | 3 | 1 |

where the value at the intersection of each row and column in the Cayley table is the product of the corresponding row and column numbers.

7. The MP decoder of claim 1, wherein the permutation network is further configured to permute the messages in accordance with a parity-check matrix of the non-binary LDPC code.

8. The MP decoder of claim 1, wherein the permutation network is further configured to be dynamically reconfigured to permute messages in accordance with a Cayley table that describes a multiplication operation of a finite Galois field or general linear group.

9. A method, comprising:
receiving a message from a check-node for decoding a non-binary low-density parity-check (LDPC) code over a non-associative finite division near ring;
permuting the message in accordance with a Cayley table that describes a multiplication operation of the non-associative finite division near ring; and
providing the permuted message to a variable-node.

10. The method of claim 9, further comprising:
receiving, by the check node, messages from a plurality of variable-nodes connected to the check-node; and
computing, by the check node, the message, in an extrinsic manner, as a function of the messages from the plurality of variable-nodes.

11. The method of claim 9, wherein the Cayley table is given by:

| x | 0 | 1 | 2 | 3 |
|---|---|---|---|---|
| 0 | 0 | 0 | 0 | 0 |
| 1 | 3 | 2 | 0 | 1 |
| 2 | 2 | 1 | 3 | 0 |
| 3 | 0 | 1 | 3 | 2, |
| x | 0 | 1 | 2 | 3 |
|---|---|---|---|---|
| 0 | 0 | 0 | 0 | 0 |
| 1 | 3 | 0 | 2 | 1 |
| 2 | 2 | 3 | 1 | 0 |
| 3 | 2 | 1 | 3 | 0, |

or

| x | 0 | 1 | 2 | 3 |
|---|---|---|---|---|
| 0 | 0 | 0 | 0 | 0 |
| 1 | 2 | 0 | 1 | 3 |
| 2 | 1 | 2 | 3 | 0 |
| 3 | 1 | 3 | 2 | 0 |

where the value at the intersection of each row and column in the Cayley table is the product of the corresponding row and column numbers.

12. The method of claim 9, wherein the Cayley table is given by:

| x | 0 | 1 | 2 | 3 |
|---|---|---|---|---|
| 0 | 0 | 0 | 0 | 0 |
| 1 | 3 | 1 | 0 | 2 |
| 2 | 2 | 1 | 0 | 3 |
| 3 | 2 | 0 | 1 | 3 |
| 3 | 0 | 2 | 3 | 1, |
| x | 0 | 1 | 2 | 3 |
|---|---|---|---|---|
| 0 | 0 | 0 | 0 | 0 |
| 1 | 2 | 3 | 0 | 1 |
| 2 | 1 | 3 | 0 | 2 |
| 3 | 1 | 0 | 3 | 2 |
| 3 | 0 | 1 | 2 | 3, |

or

| x | 0 | 1 | 2 | 3 |
|---|---|---|---|---|
| 0 | 0 | 0 | 0 | 0 |
| 1 | 3 | 1 | 0 | 2 |
| 2 | 2 | 1 | 0 | 3 |
| 3 | 2 | 0 | 1 | 3 |
| 3 | 0 | 2 | 3 | 1 |

where the value at the intersection of each row and column in the Cayley table is the product of the corresponding row and column numbers.

13. The method of claim 9, wherein permuting the message further comprises:
permuting the message in accordance with a parity-check matrix of the non-binary LDPC code.

14. The method of claim 9, further comprising:
receiving a message from the variable-node for decoding the non-binary LDPC code over the non-associative finite division near ring;
permuting the message from the variable-node in accordance with the Cayley table that describes the multiplication operation of the non-associative finite division near ring; and
providing the permuted message from the variable-node to the check-node.

15. A message passing (MP) decoder, comprising:
a variable-node;
a check-node; and
a permutation network configured to receive a message from the check-node for decoding a non-binary low-density parity-check (LDPC) code over a non-associative finite division near ring, permute the message in accordance with a Cayley table that describes a multiplication operation of the non-associative finite division near ring, and provide the permuted message to the variable-node.

16. The MP decoder of claim 15, wherein the Cayley table is given by:

| x | 0 | 1 | 2 | 3 |
|---|---|---|---|---|
| 0 | 0 | 0 | 0 | 0 |
| 1 | 3 | 2 | 0 | 1 |
| 2 | 2 | 1 | 3 | 0 |
| 3 | 0 | 1 | 3 | 2, |
| x | 0 | 1 | 2 | 3 |
|---|---|---|---|---|
| 0 | 0 | 0 | 0 | 0 |
| 1 | 3 | 0 | 2 | 1 |
| 2 | 2 | 3 | 1 | 0 |
| 3 | 2 | 1 | 3 | 0, |

or

| x | 0 | 1 | 2 | 3 |
|---|---|---|---|---|
| 0 | 0 | 0 | 0 | 0 |
| 1 | 2 | 0 | 1 | 3 |
| 2 | 1 | 2 | 3 | 0 |
| 3 | 1 | 3 | 2 | 0 |

where the value at the intersection of each row and column in the Cayley table is the product of the corresponding row and column numbers.

17. The MP decoder of claim 15, wherein the Cayley table is given by:

| x | 0 | 1 | 2 | 3 |
|---|---|---|---|---|
| 0 | 0 | 0 | 0 | 0 |
| 1 | 3 | 1 | 0 | 2 |
| 2 | 2 | 1 | 0 | 3 |
| 3 | 2 | 0 | 1 | 3 |
| 3 | 0 | 2 | 3 | 1, |
| x | 0 | 1 | 2 | 3 |
|---|---|---|---|---|
| 0 | 0 | 0 | 0 | 0 |
| 1 | 2 | 3 | 0 | 1 |
| 2 | 1 | 3 | 0 | 2 |
| 3 | 1 | 0 | 3 | 2 |
| 3 | 0 | 1 | 2 | 3, |

or

| x | 0 | 1 | 2 | 3 |
|---|---|---|---|---|
| 0 | 0 | 0 | 0 | 0 |
| 1 | 3 | 1 | 0 | 2 |
| 2 | 2 | 1 | 0 | 3 |
| 3 | 2 | 0 | 1 | 3 |
| 3 | 0 | 2 | 3 | 1 |

where the value at the intersection of each row and column in the Cayley table is the product of the corresponding row and column numbers.

18. A method, comprising:
receiving a message to be encoded for a non-binary low-density parity-check (LDPC) code over a non-associative finite division near ring;
encoding the message based on a generator matrix or a parity check matrix in accordance with a Cayley table that describes a multiplication operation of the non-associative finite division near ring to produce a codeword; and
providing the codeword as output.

19. The method of claim 18, wherein the Cayley table is given by:

| x | 0 | 1 | 2 | 3 |
|---|---|---|---|---|
| 0 | 0 | 0 | 0 | 0 |
| 1 | 3 | 2 | 0 | 1 |
| 2 | 2 | 1 | 3 | 0 |
| 3 | 0 | 1 | 3 | 2, |
| x | 0 | 1 | 2 | 3 |
|---|---|---|---|---|
| 0 | 0 | 0 | 0 | 0 |
| 1 | 3 | 0 | 2 | 1 |
| 2 | 2 | 3 | 1 | 0 |
| 3 | 2 | 1 | 3 | 0, |

or

| x | 0 | 1 | 2 | 3 |
|---|---|---|---|---|
| 0 | 0 | 0 | 0 | 0 |
| 1 | 2 | 0 | 1 | 3 |
| 2 | 1 | 2 | 3 | 0 |
| 3 | 1 | 3 | 2 | 0 |

where the value at the intersection of each row and column in the Cayley table is the product of the corresponding row and column numbers.

20. The method of claim 18, wherein the Cayley table is given by:

| x | 0 | 1 | 2 | 3 |
|---|---|---|---|---|
| 0 | 0 | 0 | 0 | 0 |
| 1 | 3 | 1 | 0 | 2 |
| 2 | 2 | 1 | 0 | 3 |
| 3 | 2 | 0 | 1 | 3 |
| 3 | 0 | 2 | 3 | 1, |
| x | 0 | 1 | 2 | 3 |
|---|---|---|---|---|
| 0 | 0 | 0 | 0 | 0 |
| 1 | 2 | 3 | 0 | 1 |
| 2 | 1 | 3 | 0 | 2 |
| 3 | 1 | 0 | 3 | 2 |
| 3 | 0 | 1 | 2 | 3, |

or

| x | 0 | 1 | 2 | 3 |
|---|---|---|---|---|
| 0 | 0 | 0 | 0 | 0 |
| 1 | 3 | 1 | 0 | 2 |
| 2 | 2 | 1 | 0 | 3 |
| 3 | 2 | 0 | 1 | 3 |
| 3 | 0 | 2 | 3 | 1 |

where the value at the intersection of each row and column in the Cayley table is the product of the corresponding row and column numbers.
